(19) United States
(12) Patent Application Publication
(10) Pub. No.: US 2026/0142448 A1
(43) Pub. Date: May 21, 2026

(54) CIRCUIT BREAKER USING SEMICONDUCTOR

(71) Applicant: LS ELECTRIC CO., LTD., Anyang-si, Gyeonggi-do (KR)

(72) Inventors: Sunghee KANG, Anyang-si, Gyeonggi-do (KR); Dongjin YUN, Anyang-si, Gyeonggi-do (KR); Jaeseop RYU, Anyang-si, Gyeonggi-do (KR)

(21) Appl. No.: 19/119,558

(22) PCT Filed: Aug. 23, 2023
(86) PCT No.: PCT/KR2023/012463

§ 371 Date: Apr. 9, 2025

(30) Foreign Application Priority Data
Dec. 22, 2022 (KR) 10-2022-0182155
Apr. 24, 2023 (KR) 10-2023-0053572

(51) Int. Cl. H02H 1/00; H02H 3/10

(52) U.S. Cl. CPC H02H 1/0007; H02H 3/105

(57) ABSTRACT

The present disclosure relates to an embodiment of a semiconductor circuit breaker in which different types of current sensors are arranged in series and sense the same current, and whether a failure has occurred is determined on the basis of the sensing result of the different types of current sensors according to the state of current inflow.

### CROSS-REFERENCE TO RELATED APPLICATIONS

This application is the National Stage filing under 35 U.S.C. 371 of International Application No. PCT/KR2023/012463, filed on Aug. 23, 2023, which claims the benefit of earlier filing date and right of priority to Korean Application No. 10-2022-0182155, filed on Dec. 22, 2022 and Korean Application No. 10-2023-0053572, filed on Apr. 24, 2023, the contents of which are all hereby incorporated by reference herein in their entirety.

### FIELD

The present disclosure relates to a circuit breaker, and more particularly, to a solid state circuit breaker (SSCB) using a power semiconductor switch.

### BACKGROUND

When a fault occurs in a power system that supplies power, an abnormal current such as an overcurrent or accident current may flow into a load through the power system. Furthermore, the abnormal current that flows thereinto may cause damage to the load. Therefore, in order to prevent the abnormal current from flowing into the load when a fault occurs in the power system, a circuit breaker that interrupts the load from the power system may be used to interrupt a current flowing into the load.

Meanwhile, in the case of a conventional mechanical circuit breaker, it takes a relatively long time of several tens of msec until the circuit is interrupted, and there is a problem in that the abnormal current flows into the load during that time. Therefore, in recent years, a solid state circuit breaker (SSCB) capable of high-speed current interruption, including a semiconductor switch made of power semiconductors capable of conducting large currents and having high-speed switching frequencies, are being used.

In the case of the solid state circuit breaker, the time to detect the current is very short compared to a circuit breaker such as a molded case circuit breaker (MCCB), so there is an advantage in that the circuit can be interrupted at high speed.

Meanwhile, in the case of an abnormal current such as a noise-induced overcurrent or an inrush current that increases momentarily but returns to a normal state within a short period of time, it does not cause damage to the load or is unlikely to cause damage, so when the circuit is interrupted due to this, the loss due to the circuit interruption may actually increase.

However, in the case of a solid state circuit breaker, since the current detection time is very short as described above, there is a problem of interrupting the circuit even when a current that does not need to be interrupted or should not be interrupted, such as the noise-induced overcurrent or inrush current, occurs. Furthermore, there is a problem in that loss may occur when normal operation of the load is not maintained as such unnecessary circuit interruptions are repeated.

### SUMMARY

An aspect of the present disclosure is to improve the limitations of the related art as described above.

Accordingly, this specification is intended to provide an embodiment that can prevent misdetermination of a fault current and unnecessary circuit interruption.

In addition, it is intended to provide an embodiment that can accurately and quickly determine a fault current.

Moreover, it is intended to provide an embodiment that can detect whether there is an abnormality in a semiconductor switch.

In order to solve the foregoing problems, the present disclosure may determine whether there is a failure based on a result of sensing a current using different types of current sensors.

Specifically, a technical feature is that different types of current sensors are arranged in a series configuration to allow the different types of current sensors to sense the same current, and determine whether there is a failure based on a sensing result of the different types of current sensors depending on an inflow state of the current.

In order to use the technical features as a means for solving the problem, an embodiment of a solid state circuit breaker herein may be a solid state circuit breaker disposed between a power supply unit and a supply target unit, and the solid state circuit breaker may include a semiconductor switch unit including a plurality of semiconductor switches in which a maximum magnitude of a current supplied from the power supply unit to the supply target unit is determined according to gate voltages applied to gate terminals, a plurality of gate drivers that apply the gate voltages to the respective plurality of semiconductor switches, one or more first current sensors provided at one or more of a first point that is a front end of the semiconductor switch unit, a second point that is between the plurality of semiconductor switches, and a third point that is a rear end of the semiconductor switch unit to sense an inflow current flowing into the semiconductor switch unit, one or more second current sensors that are different types from the first current sensors, and provided at one or more of the first point, the second point and the third point to sense the inflow current, and a control unit that determines whether the inflow current is a fault current based on a first sensing result of the first current sensor and a second sensing result of the second current sensor to control the plurality of gate drivers according to a result of the determination.

In one embodiment, one of the first current sensor and the second current sensor may be a sensor using a Hall effect measurement method.

In one embodiment, one of the first current sensor and the second current sensor may be a Hall sensor.

In one embodiment, one of the first current sensor and the second current sensor may be a sensor using a magneto resistive measurement method.

In one embodiment, one of the first current sensor and the second current sensor may be a giant magneto resistive (GMR) sensor.

In one embodiment, a sensor using the magnetic resistance measurement method may be provided at the second point to sense the inflow current using the magnetic resistance measurement method between the plurality of semiconductor switches.

In one embodiment, the first current sensor and the second current sensor may be provided at different points.

In one embodiment, the first current sensor and the second current sensor may be provided at the same point.

In one embodiment, when the first current sensor is configured in plurality, the plurality of first current sensors may be provided at different points.

In one embodiment, when the first current sensor is configured in plurality, two or more of the plurality of first current sensors may be provided at the same point.

In one embodiment, when the second current sensor is configured in plurality, the plurality of second current sensors may be provided at different points.

In one embodiment, when the sensor current sensor is configured in plurality, two or more of the plurality of second current sensors may be provided at the same point.

In one embodiment, when each of the first current sensor and the second current sensor is configured in plurality, one of the plurality of first current sensors and the plurality of second current sensors may be provided with a plurality of sensors provided at the same point, and the other may be provided with a plurality of sensors provided at the remaining points.

In one embodiment, when each of the first current sensor and the second current sensor is configured in plurality, at least one of the plurality of first current sensors and at least one of the plurality of second current sensors may be provided at the same point.

In one embodiment, the control unit may determine whether there is the fault current by varying the basis for determining whether there is the fault current for each section according to an inflow time of the inflow current.

In one embodiment, the control unit may determine whether there is the fault current based on either one of the first sensing result and the second sensing result during a first section from a first time to a second time subsequent to the inflow of the inflow current.

In one embodiment, the control unit may determine whether there is the fault current based on the other one of the first sensing result and the second sensing result during a second section from the second time to a third time subsequent to the first section.

In one embodiment, the control unit may detect a change rate of the inflow current based on the first sensing result and the second sensing result to determine whether there is the fault current by varying the basis for determining whether there is the fault current according to a result of the detection.

In one embodiment, the control unit may determines, when the change rate corresponds to a predetermined change reference, whether there is the fault current based on either one of the first sensing result and the second sensing result.

In one embodiment, the control unit may determine, when the change rate does not correspond to the predetermined change reference, whether there is the fault current based on the other one of the first sensing result and the second sensing result.

In one embodiment, the control unit may compare each of the first sensing result and the second sensing result with one or more of a first reference current and a second reference current greater than the first reference current, and determine whether there is the fault current according to a result of the comparison.

In one embodiment, the control unit may determine, as a result of the comparison, when the first sensing result and the second sensing result are above the first reference current, that the inflow current corresponds to a fault current.

In one embodiment, the control unit may determine, as a result of the comparison, when the first sensing result and the second sensing result are below the first reference current, that the inflow current does not corresponding to a fault current.

In one embodiment, the control unit may determine, as a result of the comparison, when the first sensing result is below the first reference current, and the second sensing result is above the second reference current, that the inflow current corresponds to a fault current.

In one embodiment, the control unit may determine, as a result of the comparison, when the first sensing result is above the first reference current, and the second sensing result is below the first reference current, that the inflow current does not correspond to a fault current.

In one embodiment, the control unit may control, as a result of the determination, when it is determined that the inflow current corresponds to a fault current, the plurality of gate drivers so as to allow the inflow current to be interrupted.

In one embodiment, the control unit may detect, when one or more of the first current sensor and the second current sensor are provided at each of the first point and the third point, whether there is an abnormality in the semiconductor switch unit based on a sensing result at the first point and a sensing result at the third point, and control the plurality of gate drivers according to a result of the detection.

In one embodiment, the control unit may detect that an abnormality has occurred in the semiconductor switch unit when a difference between a sensing result at the first point and a sensing result at the third point is above a reference difference.

In one embodiment, the control unit may control, as a result of the detection, when it is detected that an abnormality has occurred in the semiconductor switch unit, the plurality of gate drivers so as to allow the inflow current to be interrupted.

In one embodiment, the control unit may monitor, when one or more of the first current sensor and the second current sensor are provided at each of at least two points among the first point to the third point, a residual current at each of the at least two points based on a sensing result at each of the at least two points while the inflow current is interrupted, and detect whether there is an abnormality in the semiconductor switch unit based on a result of the monitoring.

In one embodiment, the control unit may detect that an abnormality has occurred in a semiconductor switch connected to the corresponding point when one or more of residual currents at each of the at least two points are above a reference residual current.

In one embodiment, the control unit may detect that an abnormality has occurred in a semiconductor switch provided between the corresponding points when a difference between any two of residual currents at each of the at least two points is above a reference current difference.

An embodiment of the foregoing solid state circuit breaker is not limited to those described above, and may also include embodiments described in the detailed description below or inferred/derived from the detailed description.

According to an embodiment of a solid state circuit breaker herein, a fault current may be determined based on a plurality of sensing results sensed by different types of current sensors, thereby having an effect that can accurately determine the fault current.

Accordingly, there is an effect that can prevent misdetermination of a fault current and unnecessary circuit interruption.

In addition, a plurality of sensing results at both ends of a semiconductor switch unit may be used, thereby having an effect that can detect whether there is an abnormality in a semiconductor switch.

The effects according to an embodiment of the foregoing solid state circuit breaker is not limited to those described above, and may also include effects described in the detailed description below or inferred/derived from the detailed description.

### BRIEF DESCRIPTION OF THE DRAWINGS

FIG. 1 is a circuit diagram of a solid state circuit breaker according to an embodiment.

FIGS. 2A to 2D are specific exemplary diagrams a to d of the solid state circuit breaker shown in FIG. 1.

FIG. 3 is a graph for explaining a concept of determining a fault current for each section of a solid state circuit breaker according to an embodiment.

FIG. 4 is a graph for explaining an example of determining a fault current in a solid state circuit breaker according to an embodiment.

### DETAILED DESCRIPTION

It should be noted that the technical terms used herein are merely used to describe a specific embodiment, but are not intended to limit the present disclosure. In addition, a singular expression used herein may include a plural expression unless clearly defined otherwise in the context. The suffixes “module” and “unit” used for elements in the following description are used only to simplify the disclosure, and therefore do not have meanings or functions that distinguish elements from each other in themselves

As used herein, terms such as “comprise” or “include” should not be construed to necessarily include all elements or steps described herein, and should be construed not to include some elements or some steps thereof, or should be construed to further include additional elements or steps.

In addition, in describing technologies disclosed herein, when it is determined that a detailed description of known technologies related thereto may unnecessarily obscure the subject matter disclosed herein, the detailed description will be omitted.

Furthermore, the accompanying drawings are provided only for a better understanding of the embodiments disclosed in this specification and are not intended to limit technical concepts disclosed in this specification, and therefore, it should be understood that the accompanying drawings include all modifications, equivalents and substitutes within the concept and technical scope of the present disclosure. In addition, not only respective embodiments described below, but also combinations of embodiments can of course be included within the concept and technical scope of the present disclosure as modifications, equivalents or substitutes.

First, describing a basic principle of the present disclosure to facilitate a complete understanding of the present disclosure, the present disclosure may reduce a maximum amount of current that can flow through a semiconductor switch by limiting a gate driver output voltage of the semiconductor switch that determines a current resistance output from the semiconductor switch, thereby limiting the maximum amount of current applied from a system to a load. Therefore, when a noise-induced overcurrent or inrush current occurs, the overcurrent may be suppressed so as to allow a current below an allowable current of the solid state circuit breaker to flow, thereby preventing the solid state circuit breaker from interrupting the circuit when the noise-induced overcurrent or inrush current occurs.

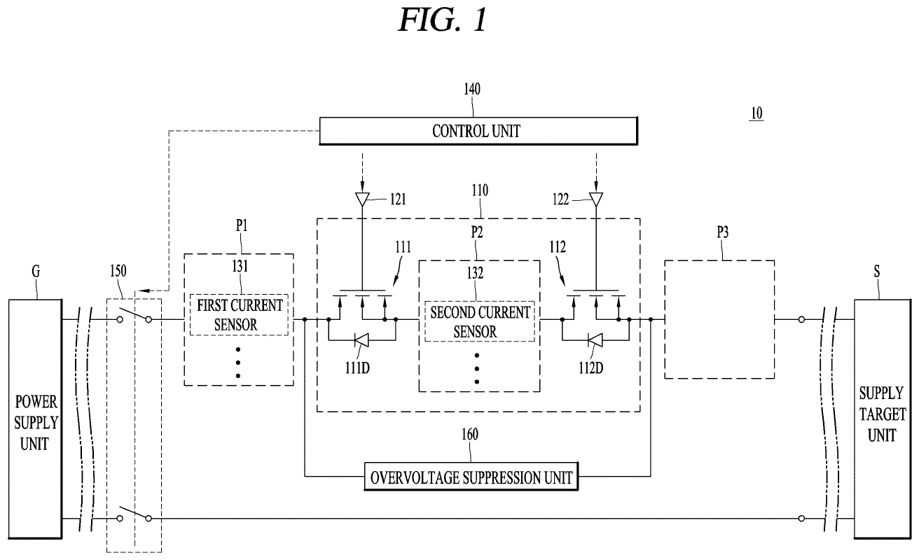

FIG. 1 is a circuit diagram showing a circuit structure of a solid state circuit breaker 10 according to an embodiment.

As shown in FIG. 1, the solid state circuit breaker 10 is disposed between a power supply unit G and a supply target unit S.

The solid state circuit breaker 10 includes a semiconductor switch unit 110 including a plurality of semiconductor switches 111, 112 that can be turned on/off and are connected in series with each other, a plurality of gate drivers 121, 122, one or more first current sensors 131, one or more second current sensors 132, and a control unit 140.

In this way, the solid state circuit breaker 10 including the semiconductor switch unit 110, the plurality of gate drivers 121, 122, the one or more first current sensors 131, the one or more second current sensors 132 and the control unit 140 may further include a cut-off switch 150 and an overvoltage suppression unit 160.

Here, the power supply unit G and the supply target unit S may be different power systems.

Alternatively, either one of the power supply unit G and the supply target unit S may be a power system and the other one may be a load.

Additionally, both the power supply unit G and the supply target unit S may be power systems.

As an example, the power supply unit G and the supply target unit S may be different micro grids.

The power supply unit G and the supply target unit S may be connected to the solid state circuit breaker 10 so as to form a bidirectional current flow not only from the power supply unit G to the supply target unit S, but also from the supply target unit S to the power supply unit G.

In addition, a current flow from the power supply unit G to the supply target unit S, a current flow from the supply target unit S to the power supply unit G, and a bidirectional current flow between the power supply unit G and the supply target unit S may be interrupted by the solid state circuit breaker 10.

For such a bidirectional interruption, the first semiconductor switch 111 and the second semiconductor switch 112 may be disposed to allow the circuit to be interrupted not only when a current flows from the power supply unit G to the supply target unit S, but also when a current flows from the supply target unit S to the power supply unit G.

As an example, the first semiconductor switch 111 and the second semiconductor switch 112 may be semiconductor switches consisting of N-Channel MOSFET elements in which the sources and drains are arranged in opposite directions.

The semiconductor switch unit 110 includes a plurality of semiconductor switches 111, 112 in which a maximum magnitude of a current supplied from the power supply unit G to the supply target unit S is determined according to gate voltages applied to gate terminals.

The plurality of semiconductor switches 111, 112 may include the first semiconductor switch 111 and the second semiconductor switch 112.

The first semiconductor switch 111 and second semiconductor switch 112 may further include first and second diodes 111D, 112D arranged in an opposite direction to a current flow to prevent damage to the MOSFET element due to a reverse voltage when the circuit is interrupted due to an accident current.

In this case, the anode and cathode of each of the first and second diodes 111D, 112D may be connected to the source terminal and drain terminal of each of the MOSFET elements 111, 112.

Therefore, the first diode 111D may be connected in parallel with the MOSFET element of the first semiconductor switch 111 and arranged in a reverse direction of a current flowing from the power supply unit G to the supply target unit S.

Additionally, the second diode 112D may be connected in parallel with the MOSFET element of the second semiconductor switch 112 and arranged in a reverse direction of a current flowing from the supply target unit S to the power supply unit G.

The solid state circuit breaker 10 may be provided with a first semiconductor switch 111 and a second semiconductor switch 112 configured in a complementary symmetrical shape to interrupt an accident current flowing in both directions.

Meanwhile, in the following description, for convenience of explanation, it is assumed that the power supply unit G is a power system and the supply target unit S is a load. However, as described above, the solid state circuit breaker 10 according to an embodiment of the present disclosure is disposed to interrupt an accident current flowing in both directions, and the present disclosure is of course not limited thereto.

The plurality of gate drivers 121, 122 include a plurality of gate drivers 121, 122 that apply gate voltages to the respective plurality of semiconductor switches 111, 112.

The plurality of gate drivers 121, 122 may include the first gate driver 121 and the second gate driver 122.

The first and second gate drivers 121, 122 may apply gate voltages to the first and second semiconductor switches 111, 112 constituting the semiconductor switch unit 110, respectively, under the control of the control unit 140.

In this case, when gate voltages exceeding threshold voltages of the respective first and second semiconductor switches 111, 112 are applied, resistance values of the output terminals of the first and second semiconductor switches 111, 112 may be smaller than those of the input terminals, and accordingly, the input terminals and the output terminals of the first and second semiconductor switches 111, 112 are conducted to form a circuit between the power supply unit G and the supply target unit S.

In this case, as the applied gate voltages increases, the resistance values of the output terminals of the first and second semiconductor switches 111, 112 may decrease.

Therefore, when adjusting the resistance values of the output terminals of the first and second semiconductor switches 111, 112 through adjusting the gate voltages, a current may flow more easily, and current magnitudes allowed in the first and second semiconductor switches 111, 112, that is, allowable current resistances, may be increased.

Therefore, a larger current may be supplied from the power supply unit G to the supply target unit S.

On the other hand, when gate voltages lower than the threshold voltages of the respective first and second semiconductor switches 111, 112 are applied, or when no gate voltages are applied, the resistance values of the output terminals of the first and second semiconductor switches 111, 112 may be equal to or larger than those of the input terminals.

Accordingly, the input and output terminals of the first and second semiconductor switches 111, 112 may not be electrically conducted, and the power supply unit G and the supply target unit S may be electrically separated (insulated) so as to interrupt the circuit connection.

In this way, in the case of the first and second semiconductor switches 111, 112, the resistance values of the output terminals of the first and second semiconductor switches 111, 112 may vary depending on voltages applied to the gate terminals through the plurality of gate drivers 121, 122, that is, output voltages of the plurality of gate drivers 121, 122.

Furthermore, depending on the resistance values of the output terminals of the first and second semiconductor switches 111, 112, a magnitude of a drain current, that is, a magnitude of a current that can be supplied through the first and second semiconductor switches 111, 112, may be determined.

Accordingly, the allowable current resistances of the first and second semiconductor switches 111, 112 may be determined according to the output voltages of the plurality of gate drivers 121, 122, and accordingly, a magnitude of a current supplied from the power supply unit G to the supply target unit S may be determined.

The one or more first current sensors 131 are provided at one or more of a first point P1 that is a front end of the semiconductor switch unit 110, a second point P2 that is between the plurality of semiconductor switches 111, 112, and a third point P3 that is a rear end of the semiconductor switch unit 110 to sense an inflow current flowing into the semiconductor switch unit 110.

The one or more second current sensors 132 are different types from the first current sensor 131, and provided at one or more of the first point P1, the second point P2, and the third point P3 to sense the inflow current.

That is, each of the one or more first current sensors 131 and the one or more second current sensors 132 may be provided at one or more of the first point P1, the second point P2, and the third point P3.

For example, as shown in FIG. 1, the first current sensor 131 may be provided at the first point P1, and the second current sensor 132 may be provided at the second point P2.

One of the first current sensor 131 and the second current sensor 132 may be a sensor that senses a current using a Hall Effect measurement method.

For example, it may be a Hall sensor.

Additionally, one of the first current sensor 131 and the second current sensor 132 may be a sensor that senses a current using a magneto resistive measurement method.

For example, it may be a giant magneto resistive (GMR) sensor.

The Hall sensor is a sensor that is robust to noise but has a slower detection speed than the GMR sensor, and the GMR sensor is a sensor that is sensitive to noise but has a faster detection speed than the Hall sensor, wherein when sensing a current with the GMR sensor in a low-speed region where the magnitude and increase time of the current are low and there is a lot of noise, the accuracy of the sensing result is lower than that of the Hall sensor due to the influence of noise, but when sensing a current with the Hall sensor in a high-speed region where the magnitude and increase time of the current are high, fast detection cannot be achieved, and thus the accuracy of the sensing result may be lower than that of the GMR sensor.

Accordingly, accurate current sensing may be achieved by sensing the current with the Hall sensor in a low-speed region where the magnitude and increase time of the current are low, and sensing the current with the GMR sensor in a high-speed region where the magnitude and increase time of the current are high.

For the first current sensor 131 and the second current sensor 132, preferably, the first current sensor 131 may be a Hall sensor, and the second current sensor 132 may be a GMR sensor.

That is, the solid state circuit breaker 10 may determine whether there is the fault current based on a result of sensing the inflow current using different types of current sensors.

Accordingly, the solid state circuit breaker 10 may determine whether there is the fault current based on different types of sensing results sensed by different types of current sensors, thereby allowing a more accurate and appropriate determination of whether there is a fault current.

Meanwhile, when either one of the first current sensor 131 and the second current sensor 132 is a sensor using the magnetic resistance measurement method, the sensor using the magnetic resistance measurement method may be provided at the second point P2 so as to sense the inflow current using the magnetic resistance measurement method between the plurality of semiconductor switches 111, 112.

For example, when the second current sensor 132 is the GMR sensor, the second current sensor 132 may be provided at the second point to sense the inflow current between the plurality of semiconductor switches 111, 112 using the magnetic resistance measurement method.

In this way, when the GMR sensor is provided at the second point P2 between the plurality of semiconductor switches 111, 112, the inflow current flowing between the plurality of semiconductor switches 111, 112 may be sensed more quickly than the Hall sensor.

In addition, the inflow current varies greatly due to the plurality of semiconductor switches 111, 112 when flowing between the plurality of semiconductor switches 111, 112, wherein when the GMR sensor that detects a change in a relative speed of a current using the magnetic resistance measurement method is provided at the second point P2, the variation of the inflow current may be sensed quickly.

Accordingly, a rapid determination of whether there is a fault current and response actions may be taken in response to a rapid and large current change, such as an accident current.

The first current sensor 131 and the second current sensor 132 may be provided at different points.

For example, as shown in FIG. 1, the first current sensor 131 may be provided at the first point P1, and the second current sensor 132 may be provided at the second point P2.

The first current sensor 131 and the second current sensor 132 may also be provided at the same point.

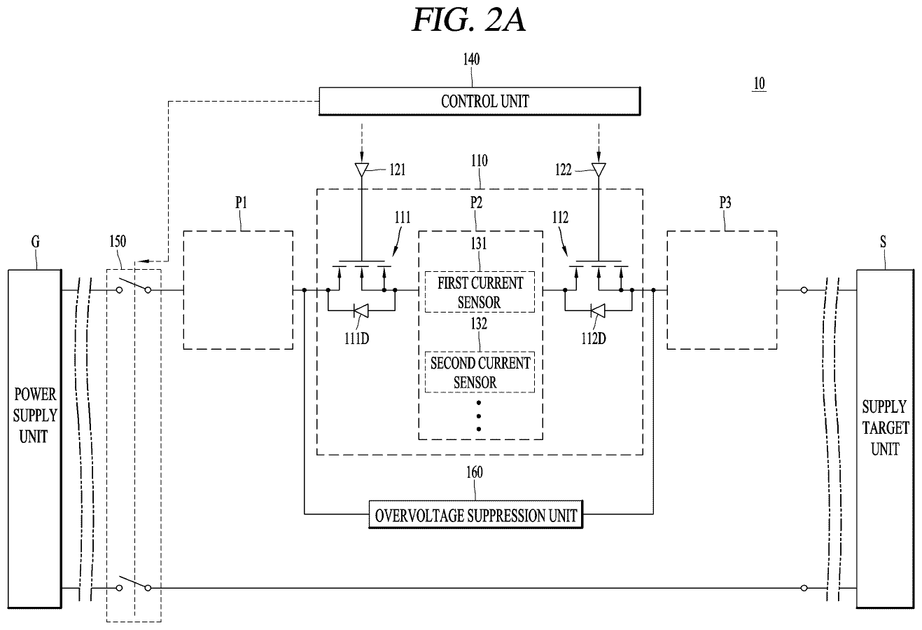

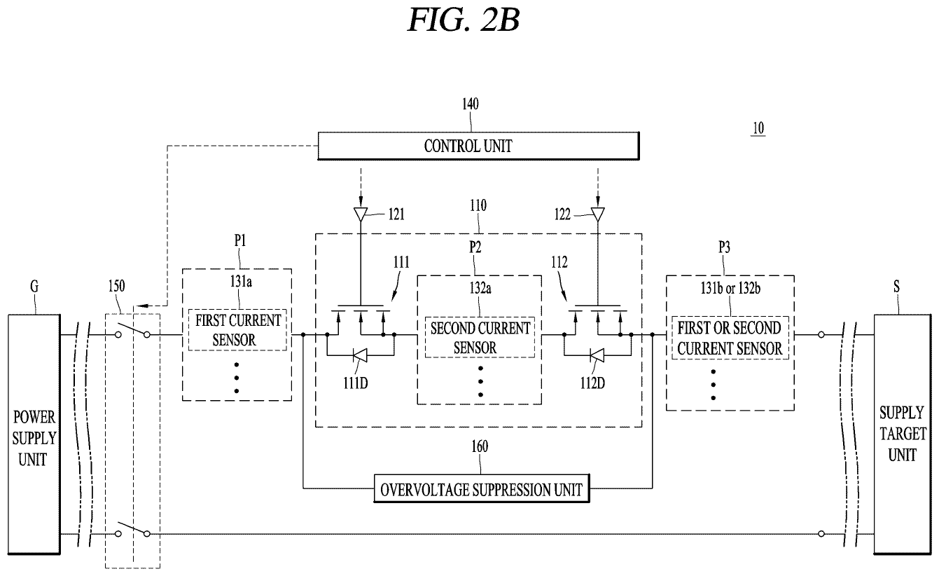

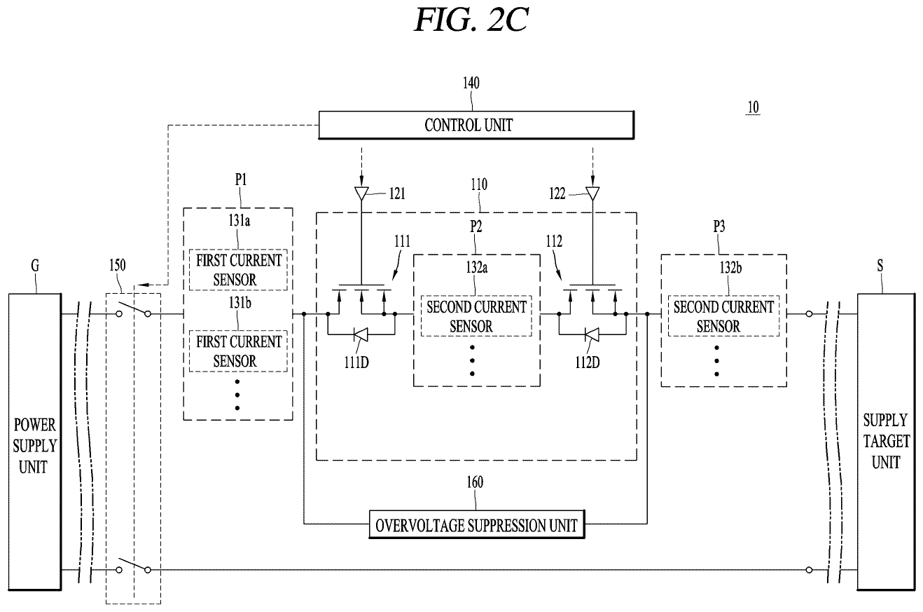

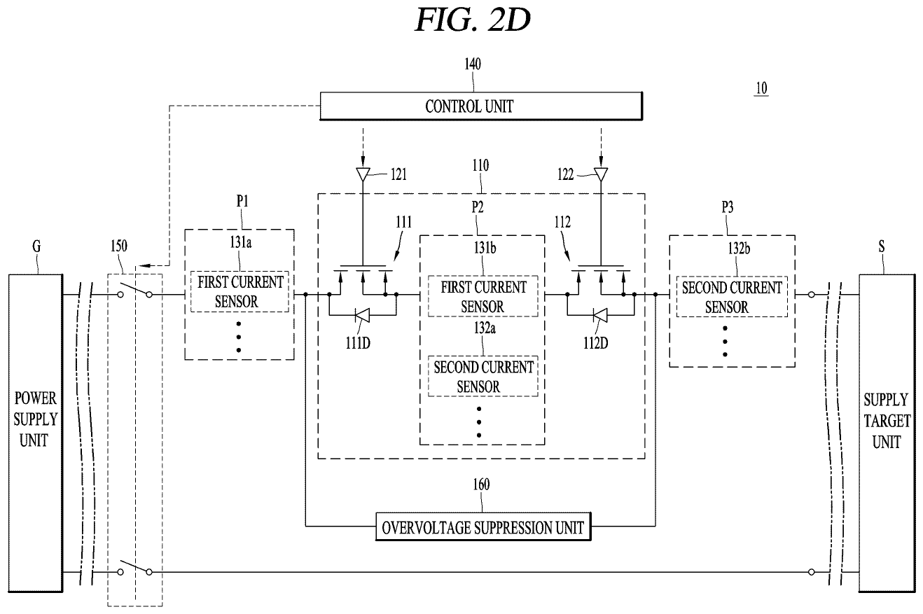

For example, as shown in FIG. 2A, the first current sensor 131 and the second current sensor 132 may be provided at the second point P2.

Meanwhile, when the first current sensor 131 is configured in plurality, the plurality of first current sensors 131 may be provided at different points.

For example, as shown in FIG. 2B, the first-first current sensor 131a may be provided at the first point P1, and the first-second current sensor 131b may be provided at the third point P3.

When the second current sensor 132 is configured in plurality, the plurality of second current sensors 132 may be provided at different points.

For example, as shown in FIG. 2B, the second-first current sensor 132a may be provided at the second point P2, and the second-second current sensor 132b may be provided at the third point P3.

In addition, when the first current sensor 131 is configured in plurality, two or more of the plurality of first current sensors 131 may be provided at the same point.

For example, as shown in FIG. 2C, both the first-first current sensor 131a and the first-second current sensor 131b may be provided at the first point P1.

Meanwhile, when the second current sensor 132 is configured in plurality, two or more of the plurality of second current sensors 132 may be provided at the same point.

When each of the first current sensor 131 and the second current sensor 132 is configured in plurality, one of the plurality of first current sensors 131 and the plurality of second current sensors 132 may be provided with plurality of sensors at the same point, and the other one may be provided with the plurality of sensors at the remaining points.

For example, as shown in FIG. 2C, the first current sensor 131 may be provided with the first-first current sensor 131a and the first-second current sensor 131b at the first point P1, the second current sensor 132 may be provided with the second-first current sensor 132a at the second point P2, and the second-second current sensor 132b at the third point P3.

When each of the first current sensor 131 and the second current sensor 132 is configured in plurality, one or more of the plurality of first current sensors 131 and one or more of the plurality of second current sensors may be provided at the same point.

For example, as shown in FIG. 2D, the first current sensor 131 may be provided with the first-first current sensor 131a at the first point P1, the first-second current sensor 131b at the second point P2, and the second current sensor 132 may be provided with the second-first current sensor 132a at the second point P1, and the second-second current sensor 132b at the third point P3.

The first current sensor and the second current sensor 131, 132 may sense the inflow current flowing into the semiconductor switch unit 110 to transmit a result of the sensing to the control unit 140.

The control unit 140 determines whether the inflow current is a fault current based on a first sensing result of the first current sensor 131 and a second sensing result of the second current sensor 132, and controls the plurality of gate drivers 121, 122 according to a result of the determination.

The control unit 140 may determine whether there is the fault current by varying the basis for determining whether there is the fault current for each section according to an inflow time of the inflow current.

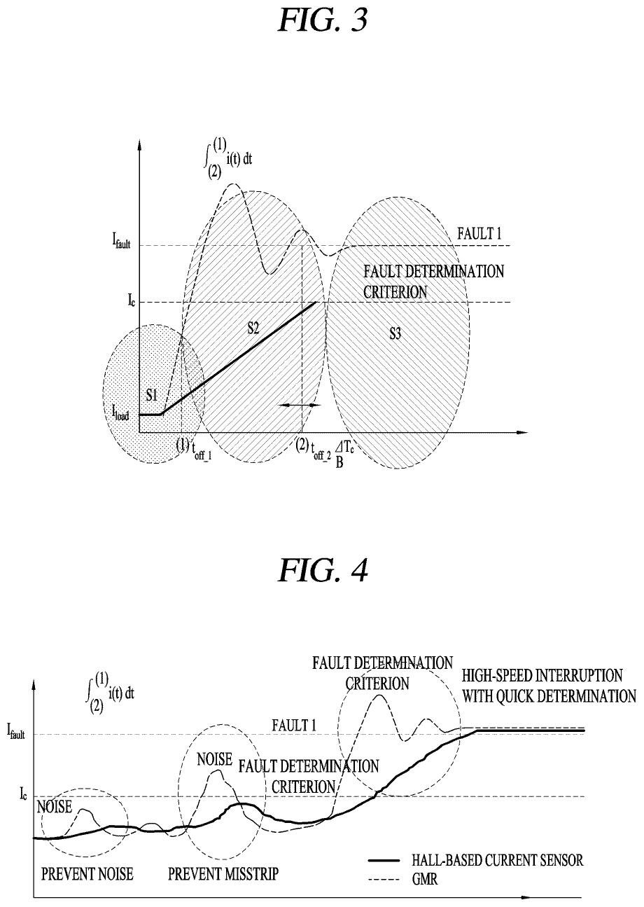

For example, as shown in FIG. 3, the inflow current is divided into a zeroth section S1, a first section S2, and a second section S3 according to an inflow time of the inflow current, whether there is the fault current may be determined by varying the basis for determining whether there is the fault current for each of the zeroth section S1, the first section S2, and the second section S3.

Here, the zeroth section S1 may be an initial section in which the inflow current is introduced, the first section S2 may be a section in which an increase rate of the inflow current is faster than a predetermined increase reference subsequent to the zeroth section S1, and the second section S3 may be a section in which an increase rate of the inflow current is slower than the predetermined increase reference subsequent to the first section S2.

The control unit 140 may determine whether there is the fault current based on a DESAT voltage detection result of the semiconductor switch unit 110 during the zeroth section S1 to a first time t_{off_1} subsequent to the inflow current being introduced.

The control unit 140 may determine whether there is the fault current based on either one of the first sensing result and the second sensing result during the first section S2 from a first time t_{off_1} to a second time t_{off_2} subsequent to the inflow current being introduced.

That is, the control unit 140 may determine whether there is the fault current based on either one of the first sensing result and the second sensing result from the first time t_{off_1} to the second time t_{off_2} in which an increase rate of the inflow current is faster than the predetermined increase reference.

The control unit 140 may determine whether there is the fault current based on a result of the sensing corresponding to the GMR sensor among the first sensing result and the second sensing result during the first section S2 from the first time t_{off_1} to the second time t_{off_2}.

For example, when the first current sensor 131 is the Hall sensor and the second current sensor 132 is the GMR sensor, whether there is the fault current may be determined based on a sensing result of the second current sensor 132 during the first section S2.

That is, the control unit 140 may determine whether there is the fault current based on a sensing result of the GMR sensor when corresponding to the first section S1 in which an increase rate of the inflow current is faster than the predetermined increase reference.

Accordingly, whether there is the fault current may be determined based on a sensing result of the GMR sensor having a fast sensing speed of the inflow current during the first section S1 in which an increase rate of the inflow current is faster than the predetermined increase reference, thereby quickly determining whether there is the fault current in a section in which the inflow current increases rapidly.

The control unit 140 may determine whether there is the fault current based on the other one of the first sensing result and the second sensing result during the second period S3 from the second time t_{off_2} to a third time subsequent to the first section S2.

That is, the control unit 140 may determine whether there is the fault current based on one sensing result based on the first section S2 and the other one among the first sensing result and the second sensing result, from the second time t_{off_2} when an increase rate of the inflow current is slower than the predetermined increase reference.

The control unit 140 may determine whether there is the fault current based on a result of the sensing corresponding to the Hall sensor among the first sensing result and the second sensing result during the second section S3 from the second time t_{off_2} to a third time subsequent to the first section S2.

For example, when the first current sensor 131 is the Hall sensor, the second current sensor 132 is the GMR sensor, and whether there is the fault current is determined based on a sensing result of the GMR sensor during the first section S2, whether there is the fault current may be determined based on a sensing result of the first current sensor 131 during the second section S3.

That is, the control unit 140 may determine whether there is the fault current based on a sensing result of the Hall sensor when corresponding to the second section S3 in which an increase rate below inflow current is slower than the predetermined increase reference.

Accordingly, during the second section S2 in which an increase rate of the inflow current is slower than the predetermined increase reference, whether there is the fault current may be determined based on a sensing result of the Hall sensor that is robust to noise of the inflow current, thereby accurately determining whether there is the fault current in a section with a lot of noise.

In this way, as shown in FIG. 3, the control unit 140 may determine whether there is the fault current based on a DESAT voltage detection result during the zeroth section S1, based on a sensing result of the GMR sensor during the first section S2, and based on a sensing result of the Hall sensor during the second section S3.

Meanwhile, the control unit 140 may detect a change rate of the inflow current based on the first sensing result and the second sensing result to determine whether there is the fault current by varying the basis for determining whether there is the fault current according to a result of the detection.

The control unit 140 may detect the change rate based on the first sensing result and the second sensing result to determine whether there is the fault current by varying the basis for determining whether there is the fault current based on a result of comparing the change rate with a predetermined change reference.

The control unit 140 may determine whether there is the fault current based on either one of the first sensing result and the second sensing result when the change rate corresponds to the predetermined change reference.

The control unit 140 may determine whether there is the fault current based on a result of the sensing corresponding to the GMR sensor among the first sensing result and the second sensing result when the change rate corresponds to the predetermined change reference.

That is, the control unit 140 may determine whether there is the fault current based on a sensing result of the GMR sensor, which is easy to detect at high speed, when the change rate changes rapidly according to the predetermined change reference.

For example, when the first current sensor 131 is the Hall sensor and the second current sensor 132 is the GMR sensor, whether there is the fault current may be determined based on the second sensing result when the change rate corresponds to the predetermined change reference.

The control unit 140 may determine whether there is the fault current based on the other one of the first sensing result and the second sensing result when the change rate does not correspond to the predetermined change reference.

The control unit 140 may determine whether there is the fault current based on a result of the sensing corresponding to the Hall sensor among the first sensing result and the second sensing result when the change rate does not correspond to the predetermined change reference.

That is, when the change rate does not correspond to the predetermined change reference and changes slowly, the control unit 140 may determine whether there is the fault current based on a sensing result of the Hall sensor that is easy to detect at low speed.

For example, when the first current sensor 131 is the Hall sensor and the second current sensor 132 is the GMR sensor, whether there is the fault current may be determined based on the first sensing result when the change rate does not correspond to the predetermined change reference.

In this way, as shown in FIG. 4, the control unit 140 may determine whether there is the fault current based on a sensing result of the GMR sensor when the change rate corresponds to the predetermined change reference, and based on a sensing result of the Hall sensor when the change rate does not correspond to the predetermined change reference.

The control unit 140 may compare each of the first sensing result and the second sensing result with one or more of a first reference current and a second reference current greater than the first reference current, and determine whether there is the fault current according to a result of the comparison.

Here, the first reference current may be an overcurrent reference at which the solid state circuit breaker 10 operates, and the second reference current may be a maximum overcurrent reference at which the solid state circuit breaker 10 is damaged.

Hereinafter, for convenience of explanation, it is assumed that the first sensing result is a sensing result of the Hall sensor, and the second sensing result is a sensing result of the GMR sensor.

The control unit 140 may determine that the inflow current corresponds to a fault current as a result of the comparison, when the first sensing result and the second sensing result are above the first reference current.

That is, the control unit 140 may determine that a fault current has occurred when the sensing result of the Hall sensor and the sensing result of the GMR sensor are above the first reference current corresponding to the overcurrent reference.

The control unit 140 may determine that the inflow current does not correspond to a fault current as a result of the comparison, when the first sensing result and the second sensing result are below the first reference current.

That is, the control unit 140 may determine that a fault current has not occurred when the sensing result of the Hall sensor and the sensing result of the GMR sensor are below the first reference current corresponding to the overcurrent reference.

The control unit 140 may determine that the inflow current corresponds to a fault current as a result of the comparison, when the first sensing result is below the first reference current, and the second sensing result is above the second reference current.

That is, when the sensing result of the Hall sensor is below the first reference current corresponding to the overcurrent reference and the sensing result of the GMR sensor is above the second reference current corresponding to the maximum overcurrent reference, the control unit 140 may determine that the sensing result of the GMR sensor does not correspond to noise and thus a fault current has occurred.

Meanwhile, the control unit 140 may determine that the inflow current does not correspond to a fault current, as a result of the comparison, when the first sensing result is below the first reference current and the second sensing result is below the second reference current.

That is, when the sensing result of the Hall sensor is below the first reference current corresponding to the overcurrent reference and the sensing result of the GMR sensor is below the second reference current corresponding to the maximum overcurrent reference, the control unit 140 may determine that the sensing result of the GMR sensor corresponds to noise and thus no fault current is occurred.

The control unit 140 may determine that the inflow current does not correspond to a fault current, as a result of the comparison, when the first sensing result is above the first reference current and the second sensing result is below the first reference current.

That is, when the sensing result of the Hall sensor is above the first reference current corresponding to the overcurrent reference and the sensing result of the GMR sensor is below the first reference current corresponding to the overcurrent reference, the control unit 140 may determine that the sensing result of the Hall sensor corresponds to a temporary increase and thus a fault current has not occurred.

In this way, the control unit 140, as shown in FIG. 4, may determine that a fault current due to noise does not occur when the first sensing result and the second sensing result are below the first reference current I_{c}, or when the first sensing result is below the first reference current I_{c} and the second sensing result is above the first reference current I_{c}, or when the first sensing result is above the first reference current I_{c} and the second sensing result is below the first reference current I_{c}.

In addition, the control unit 140 may determine that a fault current has occurred when the first sensing result and the second sensing result are above the first reference current I_{c}, or when the first sensing result is below the first reference current I_{c} and the second sensing result is above the second reference current I_{fault}.

The control unit 140 may control the plurality of gate drivers 121, 122 so as to interrupt the inflow current, as a result of the determination, when it is determined that the inflow current corresponds to a fault current.

Meanwhile, when one or more of the first current sensor 131 and the second current sensor 132 are provided at each of the first point P1 and the third point P3, the control unit 140 may detect whether the semiconductor switch unit 110 is abnormal based on a result of sensing at the first point P1 and a result of sensing at the third point P3, and control the plurality of gate drivers 121, 122 according to a result of the detection.

That is, the control unit 140 may detect whether there is an abnormality in the semiconductor switch unit 110 based on a result of detecting the inflow current at both ends of the semiconductor switch unit 110.

For example, a result of sensing at the first point P1 and a result of sensing at the third point P3 may be compared to detect whether the semiconductor switch unit 110 is abnormal based on a difference between the two sensing results.

The control unit 140 may detect that an abnormality has occurred in the semiconductor switch unit 110 when the difference between the sensing result at the first point P1 and the sensing result at the third point P3 is above a reference difference.

That is, when the difference between the sensing result at the first point P1 and the sensing result at the third point P3 is above the reference difference, the control unit 140 may determine that an abnormality has occurred in the semiconductor switch unit 110 and thus the current sensing result at the first point P1 corresponding to a front end of the semiconductor switch unit 110 and the current sensing result at the third point P1 corresponding to a rear end of the semiconductor switch unit 110 are different, and detect the occurrence of an abnormality in the semiconductor switch unit 110.

Accordingly, the control unit 140 may detect whether there is an abnormality in the semiconductor switch unit 110 when one or more of the first current sensor 131 and the second current sensor 132 are provided at each of the first point P1 and the third point P3.

The control unit 140 may control, as a result of the detection, when detecting that an abnormality has occurred in the semiconductor switch unit 110, the plurality of gate drivers 121, 122 so as to interrupt the inflow current.

In addition, when one or more of the first current sensor 131 and the second current sensor 132 are provided at each of at least two points among the first point P1 to the third point P3, the control unit 140 may monitor a residual current at each of the at least two points based on a sensing result at each of the at least two points while the inflow current is interrupted, and detect whether the semiconductor switch unit 110 is abnormal based on a result of the monitoring.

That is, when the inflow current is interrupted while one or more of the first current sensor 131 and the second current sensor 132 are provided at each of at least two points among the first point P1 to the third point P3, the control unit 140 may detect whether the semiconductor switch unit 110 is abnormal based on a result of monitoring a residual current at each of the at least two points.

Here, the case where the inflow current is interrupted may be a state where no current flows through the solid state circuit breaker 10, or a state where the inflow current flows and is then interrupted.

That is, the residual current may refer to a current remaining at the at least two points prior to or subsequent to the inflow current flowing into the solid state circuit breaker 10.

In this way, a current sensor may be provided at each of at least two points among the first point P1 to the third point P3, thereby detecting whether each of the plurality of semiconductor switches 111, 112 is abnormal through monitoring a residual current at each of the at least two points.

The control unit 140 may detect that a problem has occurred in the semiconductor switch connected to the corresponding point when at one or more of residual currents at each of the at least two points are above the reference residual current.

That is, when the residual current is above the reference residual current, the control unit 140 may determine that an abnormality has occurred in the semiconductor switch connected to the corresponding point and thus a magnitude of the residual current is above the reference residual current, thereby detecting that an abnormality has occurred in the semiconductor switch connected to the corresponding point.

For example, the control unit 140 may detect that an abnormality has occurred in the first semiconductor switch 111 when a magnitude of the residual current at the first point P1 is above the reference residual current magnitude, detect that an abnormality has occurred in the first semiconductor switch 111 and the second semiconductor switch 112 when a magnitude of the residual current at the second point P2 is above the reference residual current magnitude, and detect that an abnormality has occurred in the second semiconductor switch 112 when a magnitude of the residual current at the third point P3 is above the reference residual current magnitude.

In addition, the control unit 140 may detect that an abnormality has occurred in a semiconductor switch provided between the corresponding points when a difference between any two of the residual currents at each of the at least two points is above a reference current difference.

That is, when a difference between any two of the residual currents at each of the at least two points is above the reference current difference, the control unit 140 may determine that an abnormality has occurred in the semiconductor switch provided between the corresponding points and thus a difference between a current at one end and a current at the other end is above the reference current difference, thereby detecting that an abnormality has occurred in the semiconductor switch provided between the corresponding points.

For example, the control unit 140 may detect that an abnormality has occurred in the first semiconductor switch 111 when a difference between the residual current at the first point P1 and the residual current at the second point P2 is above the reference current difference, and detect that an abnormality has occurred in the second semiconductor switch 111 when a difference between the residual current at the second point P2 and the residual current at the third point P3 is above the reference current difference.

As such, when one or more of the first current sensor 131 and the second current sensor 132 are provided at each of at least two points among the first point P1 to the third point P3, preferably, one or more of the first current sensor 131 and the second current sensor 132 may be provided at each of the first point P1 to the third point P3.

Accordingly, the control unit 140 may monitor a residual current at each of the first point P1 to the third point P3.

The control unit 140 may control the plurality of gate drivers 121, 122 that apply voltages to the gate terminals of the first and second semiconductor switches 111, 112.

As an example, the control unit 140 may control output voltages of the plurality of gate drivers 121, 122 so as to allow the plurality of gate drivers 121, 122 to apply a voltage greater than the threshold voltage to the gate terminals of the first and second semiconductor switches 111, 112.

In this case, since resistance values of the output terminals of the first and second semiconductor switches 111, 112 are reduced by voltages (gate driver output voltages) applied through the plurality of gate drivers 121, 122, a current supplied from the power supply unit G may be applied to the supply target unit S through the first and second semiconductor switches 111, 112.

Meanwhile, as described above, by using the characteristic that allowable current resistances of the first and second semiconductor switches 111, 112 are determined according to output voltages applied from the plurality of gate drivers 121, 122, the control unit 140 may limit a magnitude of a current flowing from one system to another system by way of the solid state circuit breaker 10.

That is, the control unit 140 may detect a current flowing from the power supply unit G to the supply target unit S or from the supply target unit S to the power supply unit G through the first and second current sensors 131, 132, and control the plurality of gate drivers 121, 122 so as to allow the plurality of gate drivers 121, 122 to apply a lower voltage than a normal state to the gate terminals of the first and second semiconductor switches 111, 112 when an overcurrent greater than a preset magnitude (normal current magnitude) or the first reference current is detected.

In this case, the allowable current resistances of the first and second semiconductor switches 121, 122 may be reduced due to the lowered gate driver output voltages, and as a result, a magnitude of a current output from the semiconductor switch unit 110 may be limited.

Therefore, a limited magnitude of a current that may not be interrupted by the solid state circuit breaker 10 may be output from the semiconductor switch unit 110, thereby preventing a connection between the power supply unit G and the supply target unit S from being interrupted due to a temporarily occurring overcurrent such as an inrush current or a noise-induced overcurrent.

In addition, the control unit 140 may control the cut-off switch 150 to connect (turn on the cut-off switch) or interrupt (turn off the cut-off switch) between the solid state circuit breaker 10 and the power supply unit G.

Here, when the solid state circuit breaker 10 is connected to the power supply unit G, the power supply unit G and the supply target unit S may be conducted and electrically connected by way of the solid state circuit breaker 10, and a current of a magnitude according to the allowable current resistance of the semiconductor switch unit 110 may be applied to another system.

Meanwhile, when the power supply unit G and the supply target unit S are conducted, the control unit 140 may detect whether an abnormal current has flowed into another system from the power supply unit G or the supply target unit S through detection values collected through the first and second current sensors 131, 132.

Here, the abnormal current may include a noise-induced overcurrent that temporarily increases and then returns to a normal level.

The abnormal current may further include a short-circuit current or ground-fault current caused by an accident occurring in either the power supply unit G or the supply target unit S, which is an overcurrent exceeding a normal range.

The short-circuit current or ground-fault current (hereinafter referred to as an accident current) has a risk of damaging, when supplied to a load or another system, a device of the load or the other system, unlike an inrush current or noise-induced overcurrent (hereinafter collectively referred to as a noise-induced overcurrent) that is temporarily applied and then restored to a normal state.

Therefore, when an abnormal current is detected, the control unit 140 may distinguish between the accident current and the noise-induced overcurrent based on a magnitude of the detected overcurrent or a duration of the overcurrent.

Furthermore, when the detected overcurrent is an accident current, the semiconductor switch unit 110 and the cut-off switch 150 may be controlled to interrupt a connection between the power supply unit G and the supply target unit S.

On the contrary, when the detected overcurrent is a noise-induced overcurrent, the control unit 140 may limit output voltages of the plurality of gate drivers 121, 122 as described above, thereby limiting the allowable current resistance of the semiconductor switch unit 110.

Therefore, a magnitude of a current output from the semiconductor switch unit 110 may be suppressed to be below a current magnitude allowed by the solid state circuit breaker 10, thereby preventing unnecessary circuit interruption of the solid state circuit breaker 10 due to the noise-induced overcurrent.

Meanwhile, the control unit 140 may restore, as a result of detection by the first and second current sensors 131, 132, when a noise-induced overcurrent generated in one system disappears, a current flowing from the one system to another system to a normal magnitude.

Then, the control unit 140 may restore output voltages of the plurality of gate drivers 121, 122 to a normal state, thereby restoring an allowable current resistance of the semiconductor switch unit 110.

Meanwhile, the control unit 140 may of course limit output voltages of the plurality of gate drivers 121, 122 for a preset period of time when the noise-induced overcurrent is detected, due to the characteristics of the noise-induced overcurrent that occurs temporarily.

In this case, when a preset period of time elapses sufficiently for the noise-induced overcurrent to disappear, the control unit 140 may restore the output voltages of the plurality of gate drivers 121, 122 to a normal state.

To this end, the control unit 140 may include a timer (not shown) that can check whether the predetermined period of time has elapsed.

Meanwhile, in the foregoing description, it has been described that the semiconductor switch includes an N-channel MOSFET element as an example, but the present disclosure is not of course limited thereto.

As an example, the first and second semiconductor switches 111, 112 may be any element that can be turned on/off by a gate drive voltage applied by the control unit 140, such as an IGBT, GTO, or IGCT, instead of the MOSFET element.

The cut-off switch 150 may interrupt a connection from one system to the solid state circuit breaker 10 and another system.

The cut-off switch 150 may be a mechanical switch, and may physically isolate the solid state circuit breaker 10 to interrupt it from the power system in which an accident has occurred.

The cut-off switch 150 may be disposed between the power supply unit G and the semiconductor switch unit 110 as shown in FIG. 1.

Meanwhile, the location of the cut-off switch 150 is not of course limited thereto, and may of course be disposed in any other location (e.g., between the supply target unit S and the semiconductor switch unit 110).

The overvoltage suppression unit 160 may prevent overvoltage from being formed at both ends of the semiconductor switch unit 110 due to a residual current when the solid state circuit breaker 10 cuts off the circuit due to an accident current.

The overvoltage suppression unit 160 may include a snubber circuit or an element for overvoltage suppression, for example, a transient voltage suppressor (TVS) element.

Alternatively, the overvoltage suppression unit 160 may include free wheeling circuits formed of at least one diode and resistor, and each connected to both ends of the semiconductor switch unit 110.

Although embodiments of a solid state circuit breaker have been described so far, the described embodiments may be modified in various ways without departing from the scope of the present disclosure, and the scope of the present disclosure should not be limited to the described embodiments, but should be defined not only by the claims described below but also by equivalents of the claims.

### DESCRIPTION OF REFERENCE NUMERALS

10: Solid state circuit breaker 110: Semiconductor switch unit
111: First semiconductor switch 112: Second semiconductor switch
121: First gate driver 122: Second gate driver
131: First current sensor 132: Second current sensor
140: Control unit 150: Cut-off switch
160: Overvoltage suppression unit

1. A solid state circuit breaker disposed between a power supply unit and a supply target unit, the solid state circuit breaker comprising:
a semiconductor switch unit comprising a plurality of semiconductor switches in which a maximum magnitude of a current supplied from the power supply unit to the supply target unit is determined according to gate voltages applied to gate terminals;
a plurality of gate drivers that apply the gate voltages to the respective plurality of semiconductor switches;
one or more first current sensors provided at one or more of a first point that is a front end of the semiconductor switch unit, a second point that is between the plurality of semiconductor switches, and a third point that is a rear end of the semiconductor switch unit to sense an inflow current flowing into the semiconductor switch unit;
one or more second current sensors that are different types from the first current sensors, and provided at one or more of the first point, the second point and the third point to sense the inflow current; and
a control unit that determines whether the inflow current is a fault current based on a first sensing result of the first current sensor and a second sensing result of the second current sensor to control the plurality of gate drivers according to a result of the determination.

2. The solid state circuit breaker of claim 1, wherein one of the first current sensor and the second current sensor is a sensor using a Hall effect measurement method.

3. The solid state circuit breaker of claim 1, wherein one of the first current sensor and the second current sensor is a sensor using a magneto resistive measurement method.

4. The solid state circuit breaker of claim 3, wherein a sensor using the magnetic resistance measurement method is provided at the second point to sense the inflow current using the magnetic resistance measurement method between the plurality of semiconductor switches.

5. The solid state circuit breaker of claim 1, wherein the first current sensor and the second current sensor are provided at different points.

6. The solid state circuit breaker of claim 1, wherein the first current sensor and the second current sensor are provided at the same point.

7. The solid state circuit breaker of claim 1, wherein the control unit determines whether there is the fault current by varying the basis for determining whether there is the fault current for each section according to an inflow time of the inflow current.

8. The solid state circuit breaker of claim 7, wherein the control unit determines whether there is the fault current based on either one of the first sensing result and the second sensing result during a first section from a first time to a second time subsequent to the inflow of the inflow current, and determines whether there is the fault current based on the other one of the first sensing result and the second sensing result during a second section from the second time to a third time subsequent to the first section.

9. The solid state circuit breaker of claim 1, wherein the control unit detects a change rate of the inflow current based on the first sensing result and the second sensing result to determine whether there is the fault current by varying the basis for determining whether there is the fault current according to a result of the detection.

10. The solid state circuit breaker of claim 9, wherein the control unit determines, when the change rate corresponds to a predetermined change reference, whether there is the fault current based on either one of the first sensing result and the second sensing result, and determines, when the change rate does not correspond to the predetermined change reference, whether there is the fault current based on the other one of the first sensing result and the second sensing result.

11. The solid state circuit breaker of claim 1, wherein the control unit compares each of the first sensing result and the second sensing result with one or more of a first reference current and a second reference current greater than the first reference current, and determines whether there is the fault current according to a result of the comparison.

12. The solid state circuit breaker of claim 11, wherein the control unit determines, as a result of the comparison, when the first sensing result and the second sensing result are above the first reference current, or when the first sensing result is below the first reference current and the second sensing result is above the second reference current, that the inflow current corresponds to a fault current.

13. The solid state circuit breaker of claim 11, wherein the control unit determines, as a result of the comparison, when the first sensing result and the second sensing result are below the first reference current, or when the first sensing result is above the first reference current and the second sensing result is below the first reference current, that the inflow current does not correspond to a fault current.

14. The solid state circuit breaker of claim 1, wherein the control unit controls, as a result of the determination, when it is determined that the inflow current corresponds to a fault current, the plurality of gate drivers so as to allow the inflow current to be interrupted.

15. The solid state circuit breaker of claim 1, wherein the control unit detects, when one or more of the first current sensor and the second current sensor are provided at each of the first point and the third point, whether there is an abnormality in the semiconductor switch unit based on a sensing result at the first point and a sensing result at the third point, and controls the plurality of gate drivers according to a result of the detection.

16. The solid state circuit breaker of claim 15, wherein the control unit detects that an abnormality has occurred in the semiconductor switch unit when a difference between a result of the sensing at the first point and a result of the sensing at the third point is above a reference difference.

17. The solid state circuit breaker of claim 15, wherein the control unit controls, as a result of the detection, when it is detected that an abnormality has occurred in the semiconductor switch unit, the plurality of gate drivers so as to allow the inflow current to be interrupted.

18. The solid state circuit breaker of claim 1, wherein the control unit monitors, when one or more of the first current sensor and the second current sensor are provided at each of at least two points among the first point to the third point, a residual current at each of the at least two points based on a result of the sensing at each of the at least two points while the inflow current is interrupted, and detects whether there is an abnormality in the semiconductor switch unit based on a result of the monitoring.

19. The solid state circuit breaker of claim 18, wherein the control unit detects that an abnormality has occurred in a semiconductor switch connected to the corresponding point when one or more of residual currents at each of the at least two points are above a reference residual current.

20. The solid state circuit breaker of claim 18, wherein the control unit detects that an abnormality has occurred in a semiconductor switch provided between the corresponding points when a difference between any two of residual currents at each of the at least two points is above a reference current difference.
